(19) United States
(12) Patent Application Publication
(10) Pub. No.: US 2025/0248191 A1
(43) Pub. Date: Jul. 31, 2025

(54) STAMP, METHOD FOR MANUFACTURING THE SAME, TRANSFER DEVICE, AND MASS TRANSFER METHOD

(71) Applicants: Beijing BOE Technology Development Co., Ltd., Beijing (CN); BOE TECHNOLOGY GROUP CO., LTD., Beijing (CN)

(72) Inventors: Shulei LI, Beijing (CN); Menghua ZHAO, Beijing (CN); Miaomiao JIA, Beijing (CN); Ying ZHOU, Beijing (CN); Yuanyuan MA, Beijing (CN); Zhao KANG, Beijing (CN); Yang LV, Beijing (CN); Ming YANG, Beijing (CN)

(21) Appl. No.: 18/699,682

(22) PCT Filed: Aug. 30, 2023
(86) PCT No.: PCT/CN2023/115680

§ 371 Date: Apr. 9, 2024

(51) Int. Cl. H10H 29/03; G03F 7/00; H01L 21/67

(52) U.S. Cl. CPC H10H 29/03; G03F 7/0015; G03F 7/0035; H01L 21/67144

(57) ABSTRACT

A stamp includes a substrate; position limiting structures located on a side of the substrate and spaced apart from each other; and transfer structures, which are located on the side of the substrate where the position limiting structures are located, and are spaced apart from each other. The position limiting structures are in one-to-one correspondence with the transfer structures. Each position limiting structure surrounds a periphery of a corresponding transfer structure, and an orthogonal projection of the position limiting structure on the substrate does not overlap with an orthogonal projection of the corresponding transfer structure on the substrate. A distance between an end surface of an end, which is distal to the substrate, of each transfer structure and the substrate is greater than a distance between an end surface of an end, which is distal to the substrate, of a corresponding position limiting structure and the substrate.

### CROSS-REFERENCE TO RELATED APPLICATIONS

This is a National Phase Application filed under 35 U.S.C. 371 as a national stage of PCT/CN2023/115680 filed on Aug. 30, 2023, the entire content of which is incorporated herein by reference.

### TECHNICAL FIELD

Embodiments of the present disclosure relate to the field of display technology, and in particular, relate to a stamp, a method for manufacturing the same, a transfer device, and a mass transfer method (which may also be referred to as “massive transfer method” or “enormous-amount transfer method”).

### BACKGROUND

A micro light emitting diode (micro LED) has characteristics such as not requiring backlight, self-luminescence, and the like, and has advantages such as simple structure, very long service lifetime, high luminance (or brightness), low power consumption, super high resolution, and the like as compared with a liquid crystal display (LCD) and an organic light emitting diode (OLED) product, thereby having promising application prospect.

### SUMMARY

In a first aspect, embodiments of the present disclosure provide a stamp, which includes a substrate;
a plurality of position limiting structures located on a side of the substrate and spaced apart from each other; and
a plurality of transfer structures, which are located on the side of the substrate where the position limiting structures are located, and are spaced apart from each other, wherein
the plurality of position limiting structures are in one-to-one correspondence with the plurality of transfer structures;
each position limiting structure surrounds a periphery of a corresponding transfer structure, and an orthogonal projection of the position limiting structure on the substrate does not overlap with an orthogonal projection of the corresponding transfer structure on the substrate; and
a distance between an end surface of an end, which is distal to the substrate, of each transfer structure and the substrate is greater than a distance between an end surface of an end, which is distal to the substrate, of a corresponding position limiting structure and the substrate.

In some embodiments, each transfer structure includes a protrusion and a viscosity adjustable layer which are superposed together in sequence away from the substrate, and
an orthogonal projection of the viscosity adjustable layer on the substrate coincides with an orthogonal projection of the protrusion on the substrate.

In another first aspect, embodiments of the present disclosure further provide a stamp, which includes a substrate;
a plurality of position limiting structures located on a side of the substrate and spaced apart from each other; and
a plurality of protrusions, which are located on the side of the substrate where the position limiting structures are located, and are spaced apart from each other, wherein
the plurality of position limiting structures are in one-to-one correspondence with the plurality of protrusions;
each position limiting structure surrounds a periphery of a corresponding protrusion, and an orthogonal projection of the position limiting structure on the substrate does not overlap with an orthogonal projection of the corresponding protrusion on the substrate;
a distance between an end surface of an end, which is distal to the substrate, of each protrusion and the substrate is greater than a distance between an end surface of an end, which is distal to the substrate, of a corresponding position limiting structure and the substrate; and
the stamp further includes a viscosity adjustable layer located on a side, which is distal to the substrate, of the position limiting structures and the protrusions, and an orthogonal projection of the viscosity adjustable layer on the substrate covers at least the protrusions.

In some embodiments, a shape of the orthogonal projection of each position limiting structure on the substrate is a ring, and
the orthogonal projection of each protrusion on the substrate and the orthogonal projection of a corresponding position limiting structure on the substrate 1 abut on each other.

In some embodiments, ⅓ of a height of each protrusion ≤ a height of a corresponding position limiting structure ≤¾ of the height of the protrusion.

In some embodiments, the height of each protrusion is in a range of 5 μm to 20 μm.

In some embodiments, wherein a linewidth of the ring of each position limiting structure is in a range of 2 μm to 30 μm.

In some embodiments, a thickness of the viscosity adjustable layer is in a range of 1 μm to 5 μm.

In some embodiments, the viscosity adjustable layer includes an adhesive sub-layer and a dissociating sub-layer, and the dissociating sub-layer and the adhesive sub-layer are superposed together in sequence away from the substrate 1;
a thickness of the adhesive sub-layer is in a range of 1 μm to 5 μm; and
a thickness of the dissociating sub-layer is in a range of 0.1 μm to 2 μm.

In some embodiments, a shape of the orthogonal projection of each protrusion on the substrate includes a circle, a rectangle, a triangle, or a polygon.

In some embodiments, the plurality of protrusions are arranged in an array to be equally spaced apart from each other; and
orthogonal projections of the plurality of protrusions on the substrate have a same shape, and orthogonal projections of any two adjacent columns of the protrusions on the substrate have different orientations; or
orthogonal projections of some of the plurality of protrusions on the substrate have a shape different from a shape of orthogonal projections of others of the plurality of protrusions on the substrate.

In some embodiments, some of the plurality of protrusions are arranged in an array to be spaced apart from each other by a first distance, and others of the plurality of protrusions are arranged in an array to be spaced apart from each other by a second distance, where the first distance is greater than the second distance.

In some embodiments, a material of each protrusion includes any one of polymethyl methacrylate, propylene glycol methyl ether acetate, silicone resin, or acrylic resin.

In some embodiments, a material of each position limiting structure includes any one of silicon oxide, silicon nitride, silicon oxynitride, copper, aluminum, molybdenum, or silver.

In some embodiments, a material of the viscosity adjustable layer includes any one of UV viscosity-reducing glue, thermal foaming viscosity-reducing glue, or laser dissociating glue;
a main material of the UV viscosity-reducing glue includes any one of epoxy acrylate, polyurethane acrylate, polyether acrylate, polyester acrylate, or acrylic resin;
a main material of the thermal foaming viscosity-reducing glue includes one or more of styrene butadiene rubber, polyisoprene rubber, polyisobutylene rubber, butyl rubber, chloroprene rubber, and nitrile rubber, foaming particles are mixed in the main material of the thermal foaming viscosity-reducing glue, a size of each of the foaming particles is in a range of 0.5 μm to 5 μm, and a filling rate of the foaming particles in the main material ranges from 2% to 10%; and
a main material of the laser dissociating glue includes one or more of acrylic resin, epoxy resin, and polymethyl methacrylate.

In some embodiments, a main material of the adhesive sub-layer includes one or more of polyether resin, epoxy resin, acrylic resin, polyisoprene resin, and polyisobutylene resin; and
a main material of the dissociating sub-layer includes one or more of polyimide resin, acrylic resin, and epoxy resin.

In some embodiments, the stamp further includes a plurality of alignment marks, which are located on the side of the substrate where the position limiting structures are located, and are located in a peripheral region or a central region of the substrate;
an orthogonal projection of each alignment mark on the substrate does not overlap with the orthogonal projection of any one of the position limiting structures on the substrate or the orthogonal projection of any one of the protrusions on the substrate, and
the alignment marks are located on a side of the viscosity adjustable layer proximal to the substrate.

In a second aspect, embodiments of the present disclosure provide a transfer device, which includes the stamp according to any one of foregoing embodiments.

In a third aspect, embodiments of the present disclosure provide a method for manufacturing a stamp, the method including:
forming a plurality of position limiting structures on a side of a substrate by a patterning process;
forming a plurality of protrusions on the side of the substrate where the above step has been completed by a patterning process, wherein the plurality of protrusions and the plurality of position limiting structures are located on the same side of the substrate; and
forming a viscosity adjustable layer on the side of the substrate where the above steps have been completed by a patterning process, wherein the viscosity adjustable layer is located on a side of the position limiting structures and the protrusions distal to the substrate, and an orthogonal projection of the viscosity adjustable layer on the substrate covers at least the protrusions.

In some embodiments, the forming a plurality of position limiting structures on a side of a substrate by a patterning process includes:
depositing a position limiting structure film on the side of the substrate;
coating a photoresist layer on a side of the position limiting structure film distal to the substrate;
exposing the photoresist layer by using a mask including patterns of the position limiting structures;
developing to remove photoresist in exposed regions of the photoresist layer;
etching and removing portions of the position limiting structure film which are not covered by the photoresist by a dry etching process or a wet etching process to form the patterns of the plurality of position limiting structures; and
stripping off the residual photoresist.

In some embodiments, the forming a plurality of protrusions on the side of the substrate where the above step has been completed by a patterning process includes:
coating an organic resin material layer on the side of the substrate;
exposing the organic resin material layer by using a mask including patterns of the protrusions; and
developing to remove portions of the organic resin material layer which are in exposed regions to form the patterns of the plurality of protrusion.

In some embodiments, the forming a viscosity adjustable layer on the side of the substrate where the above steps have been completed by a patterning process includes:
coating the viscosity adjustable layer on the side of the substrate by a spin coating process, a scrape coating process, or a slit coating process; or
coating a viscosity adjustable film on the side of the substrate, exposing the viscosity adjustable film by using a mask including a pattern of the viscosity adjustable layer, and developing to remove portions of the viscosity adjustable film which are in exposed regions, thereby forming the pattern of the viscosity adjustable layer.

In a fourth aspect, embodiments of the present disclosure provide a mass transfer method, wherein the mass transfer method includes:
pressing a stamp and a transfer substrate together, wherein the stamp is the stamp according to any one of the embodiments of the another first aspect, the transfer substrate includes a base plate and a plurality of light emitting diodes arranged on a side of the base plate, the plurality of protrusions of the stamp are in one-to-one correspondence with at least some of the light emitting diodes, the viscosity adjustable layer, of which an orthogonal projection on the base plate overlaps with orthogonal projections of the protrusions on the base plate, contacts with and stick to the light emitting diodes, and the orthogonal projections of the protrusions on the base plate covers the light emitting diodes, respectively;
pulling the stamp away from the transfer substrate to pick up at least some of the light emitting diodes on the transfer substrate;
transferring the picked up light emitting diodes to a driving substrate by the stamp, making first connecting terminals of each of the light emitting diodes correspondingly attached to second connecting terminals on the driving substrate, applying pressure to the stamp and at the same time heating the driving substrate, thereby bonding the first connecting terminals to the second connecting terminals, respectively; and
separating the stamp from the picked up light emitting diodes.

In some embodiments, each of the pressing a stamp and a transfer substrate together and the applying pressure to the stamp includes:
mechanically pressing or gaseously pressing.

In some embodiments, in a case of gaseously pressing, the stamp and the transfer substrate are attached together in a vacuum attaching device and sealed by a frame sealant, and the viscosity adjustable layer is in contact with and bonded to the light emitting diodes under an action of an external atmospheric pressure;
the light emitting diodes are transferred to the driving substrate by the stamp, the stamp and the driving substrate are attached together in the vacuum attaching device and sealed by the frame sealant, and the first connecting terminals of each of the light emitting diodes are in contact with and attached to the second connecting terminals on the driving substrate under the action of the external atmospheric pressure; and
the stamp is gaseously pressed and at the same time the driving substrate is heated, thereby bonding the first connecting terminals to the second connecting terminals, respectively.

In some embodiments, the separating the stamp from the picked up light emitting diodes includes:
performing UV light irradiation on the stamp to separate the stamp from the light emitting diodes; or
heating the stamp up to 90° C. to 150° C., to separate the stamp from the light emitting diodes; or
irradiating the stamp with laser light to separate the stamp from the light emitting diodes,
wherein a wavelength of the laser light includes 255 nm, 266 nm, 308 nm, or 355 nm.

In some embodiments, the mass transfer method further includes performing laser irradiation on portions of the transfer substrate corresponding to positions of the light emitting diodes to be picked up while the pulling the stamp away from the transfer substrate is performed, to separate the light emitting diodes to be picked up from the base plate.

### BRIEF DESCRIPTION OF THE DRAWINGS

The drawings, which are included to provide further understanding of the embodiments of the present disclosure and constitute a part of this specification, illustrate the present disclosure together with the embodiments of the present disclosure, but are not intended to limit the present disclosure. The above and other features and advantages will become more apparent to one of ordinary skill in the art by describing in detail exemplary embodiments of the present disclosure with reference to the drawings, in which:

FIG. 1a is a schematic diagram illustrating a transfer process and a transfer principle for a van der Waals force type stamp;

FIG. 1b is a schematic cross-sectional view illustrating a structure of a PDMS stamp;

FIG. 1c is a schematic diagram illustrating a displacement of a stamp structure relative to a glass substrate during a eutectic bonding process under a high temperature and a high pressure;

FIG. 2a is a schematic top view illustrating a structure of a stamp according to an embodiment of the present disclosure;

FIG. 2b is a schematic cross-sectional view illustrating a structure of the stamp shown in FIG. 2a taken along a cutting line AA′;

FIG. 2c is a schematic cross-sectional view illustrating another structure of the stamp shown in FIG. 2a taken along a cutting line AA′;

FIG. 2d is a schematic cross-sectional view illustrating another structure of the stamp shown in FIG. 2a taken along a cutting line AA′;

FIG. 2e is a schematic top view illustrating a structure of another stamp according to an embodiment of the present disclosure;

FIG. 2f is a schematic top view illustrating a structure of another stamp according to an embodiment of the present disclosure;

FIG. 2g is a schematic top view illustrating a structure of another stamp according to an embodiment of the present disclosure;

FIG. 2h is a schematic top view illustrating a structure of another stamp according to an embodiment of the present disclosure;

FIG. 2i is a schematic top view illustrating a structure of another stamp according to an embodiment of the present disclosure;

FIG. 3 is a flowchart of a process for manufacturing a stamp according to an embodiment of the present disclosure;

FIG. 4a is a process flow diagram of a mass transfer method according to an embodiment of the present disclosure; and

FIG. 4b is a process flow diagram of another mass transfer method according to an embodiment of the present disclosure.

### DETAILED DESCRIPTION OF EMBODIMENTS

To make one of ordinary skill in the art better understand technical solutions of the embodiments of the present disclosure, a stamp, a method for manufacturing a stamp, a transfer device, and a mass transfer method provided by the present disclosure will be described below in detail with reference to the accompanying drawings and exemplary embodiments.

The embodiments of the present disclosure will be described more fully hereinafter with reference to the accompanying drawings, but the embodiments shown may be embodied in different forms and should not be construed as limited to the forms set forth herein. Rather, these embodiments are provided such that the present disclosure will be thorough and complete, and will fully convey the scope of the present disclosure to one of ordinary skill in the art.

Embodiments of the present disclosure are not limited to the embodiments shown in the drawings, but include modifications of configurations formed based on a manufacturing process. Thus, the regions illustrated in the figures are exemplary, and the shapes of the regions shown in the figures illustrate exemplary shapes of the regions but are not intended to be limiting.

Mass production of micro LEDs still faces many difficulties, among which technical bottlenecks are mass transfer of the micro LEDs and mass bonding of the micro LEDs. The mass transfer of the micro LEDs includes technologies of electrostatic adsorption transfer, stamp transfer, magnetic adsorption transfer, and the like. At present, the most adopted transfer is a transfer by the van der Waals force type stamp (which may be made of polydimethylsiloxane (PDMS)), and the most adopted bonding method is eutectic bonding.

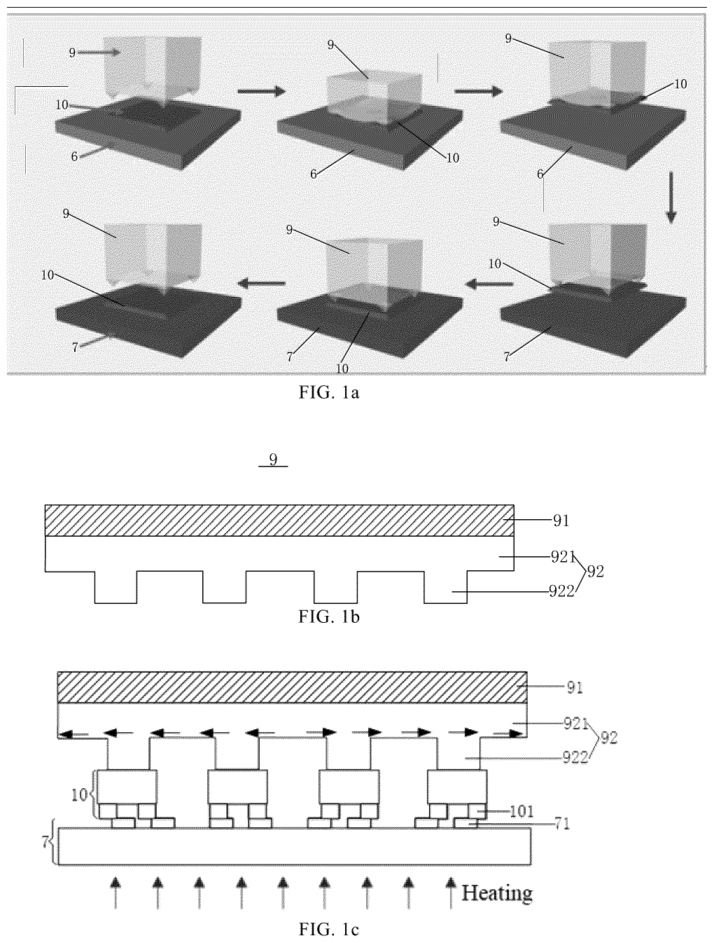

The principle and the process flow for the transfer by the van der Waals force type stamp are shown in FIGS. 1a, 1b and 1c. A PDMS stamp has certain viscosity, and an adhesion of the PDMS stamp to micro LEDs may be adjusted through a speed of lifting up the PDMS stamp. An interface adhesion of the PDMS stamp to the micro LEDs is large when the PDMS stamp is lifted up quickly, thereby picking up the micro LEDs, whereas the interface adhesion of the PDMS stamp to the micro LEDs is small (i.e., the adhesion<a bonding force between a connecting terminal of a micro LED and a connecting terminal of a driving substrate) when the PDMS stamp is lifted up slowly, thereby separating the micro LEDs from the PDMS stamp.

Referring to FIG. 1a which is a schematic diagram illustrating a transfer process and a transfer principle for a van der Waals force type stamp, an elastic PDMS stamp 9 is aligned with a micro LED device 10 on a transfer substrate 6, and is pressed down quickly; the PDMS stamp 9 is deformed and is tightly attached to the micro LED device 10; the PDMS stamp 9 is rapidly lifted up, thereby pulling up the micro LED device 10; the PDMS stamp 9 carrying the micro LED device 10 is aligned with a driving substrate 7 and is quickly pressed down; the PDMS stamp 9 is slightly shifted to one side, and is slowly lifted up; then the deformation of the PDMS stamp 9 disappears, resulting in the separation of the PDMS stamp 9 from the micro LED device 10, such that the micro LED device 10 is transferred (or transfer printed).

Although the transfer by the van der Waals force type stamp can achieve transfer of micro LEDs, there are the following technical problems to be solved, such as: firstly, there is a problem that a mass transfer technology by using a PDMS stamp is not compatible with a eutectic bonding technology. At present, bonding of connecting terminals of a micro LED device and a driving substrate is mainly achieved by using a metal eutectic bonding technology, the main scheme of the eutectic bonding is shown in the following Table 1, the metal eutectic bonding needs to be carried out under the conditions of high temperature and high pressure, and the temperature ranges from 180° C. to 300° C. The PDMS stamp made of an organic material will be aged and have changed characteristics at the high temperature. Specifically, the PDMS stamp needs to press a micro LED device all the time to provide bonding pressure during a hot-pressing eutectic bonding process, aging of the PDMS stamp at the high temperature is unavoidable, and the aging of the PDMS stamp causes an intrinsic adhesion force of the PDMS stamp to be changed, such that yields of transfer processes by using PDMS stamps in different batches are unstable. Secondly, there is a problem that a size covered by one single transfer by using the PDMS stamp is small. Referring to FIG. 1b which is a schematic cross-sectional view illustrating a structure of a PDMS stamp, the PDMS stamp 9 includes a glass substrate 91 and a stamp structure 92 disposed on the glass substrate 91, and the stamp structure 92 includes a base substrate 921 and protrusions 922 located on one side of the base substrate 921 and having a one-piece structure with the base substrate 921. It is a future product trend that the driving substrate is large-sized, however the PDMS stamp can only achieve transfer for a driving substrate with a size of 4 inches at present. When a size of the PDMS stamp is increased, on one hand, the uniformity of a height (i.e., a thickness) of the stamp structure 92 is decreased, which results in a reduced yield of transfer and bonding; on the other hand, referring to FIG. 1c, which is a schematic diagram illustrating a displacement of the stamp structure relative to the glass substrate during a eutectic bonding process under a high temperature and a high pressure, a thermal expansion coefficient (e.g., 340 ppm/° C.) of a material of the stamp structure 92 is much greater than a thermal expansion coefficient (e.g., 3.5 ppm/° C.) of the glass substrate 91, and the difference in thermal expansion coefficient causes a large accumulated deviation in displacement of the stamp structure 92 of the PDMS stamp 9 relative to the glass substrate 91 of the PDMS stamp 9 during the eutectic bonding process under the high temperature and the high pressure, such that a large alignment deviation occurs between a connecting terminal 101 of a micro LED device and a connecting terminal 71 of the driving substrate. The larger the size of the PDMS stamp 9 is, the larger the transfer accuracy drop caused by thermal expansion of the stamp structure 92 in the eutectic bonding process is, which limits the application of the PDMS stamp 9 to only small-size transfer and bonding, and thus the efficiency of the PDMS stamp 9 is low.

TABLE 1

| Bonding | Bonding type | | | |
|---|---|---|---|---|
| condition | Cu-Sn | Cu-In | Au-Sn | Au-In |
| Cleaning | Organic | 10% dilute | Organic | 10% dilute |
| | weak acid | HCl cleaning | weak acid | HCl cleaning |
| | solution or | | solution or | |
| | vapor | | vapor | |
| Atmosphere | Inert or | Inert or | Inert or | Inert or |
| | vacuum | vacuum | vacuum | vacuum |
| Reference | 250° C. to | 200° C. to | 240° C. to | 180° C. to |
| temperature | 300° C. | 280° C. | 300° C. | 200° C. |
| Reference | 1 Mpa | 0.5 Mpa | 1 Mpa | 2 Mpa |
| pressure | | | | |
| Reference | <30 min | <30 min | <30 min | <30 min |
| time | | | | |
| Bonding | 40 Mpa | 11 Mpa | 140 Mpa | 30 Mpa |
| strength (in | | | | |
| theory) | | | | |

In addition, the material cost and the manufacturing cost of the PDMS stamp are high, such that the cost for transferring a huge amount of micro LED devices by using the PDMS stamp is greatly increased.

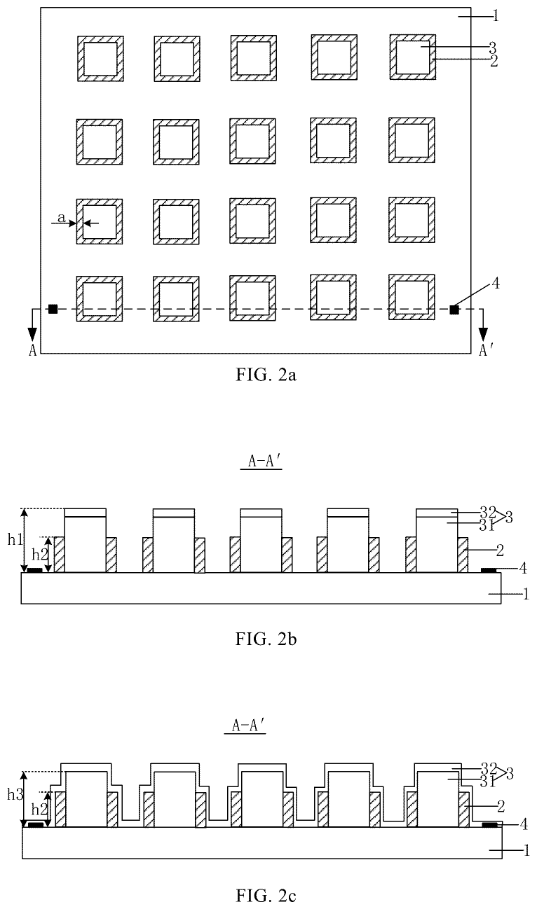

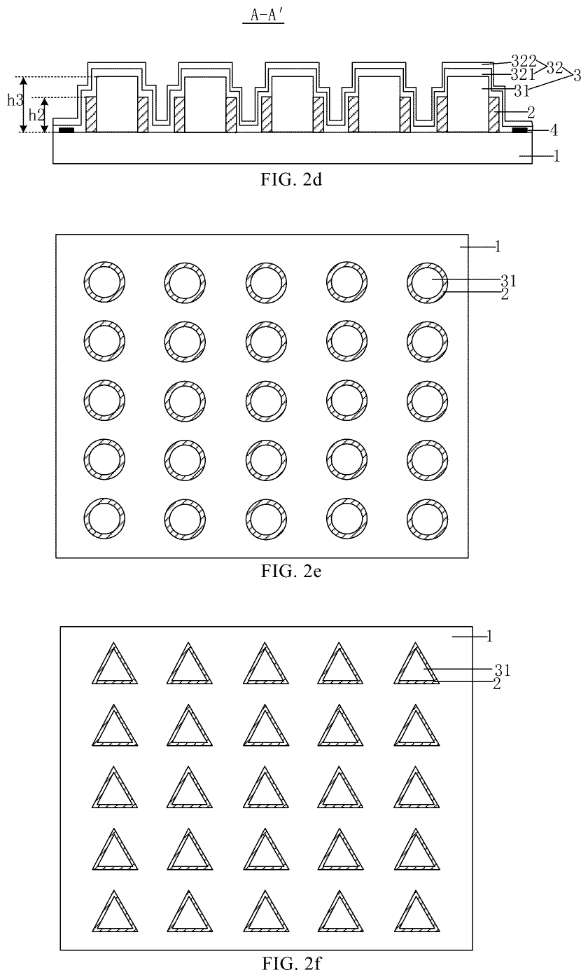

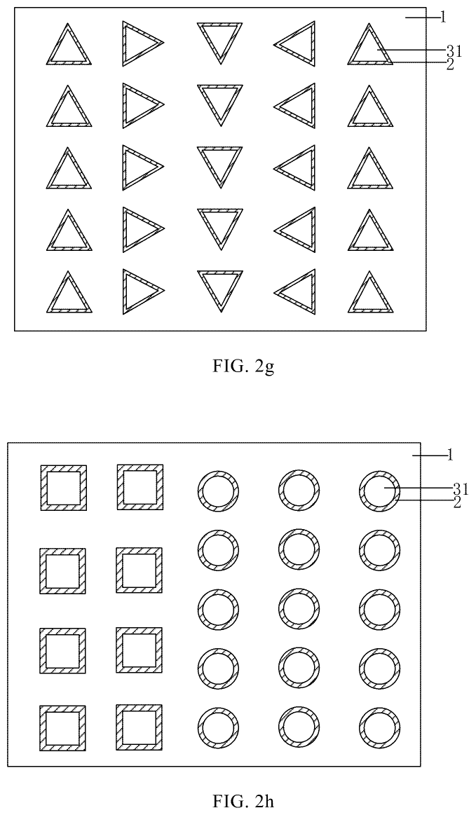

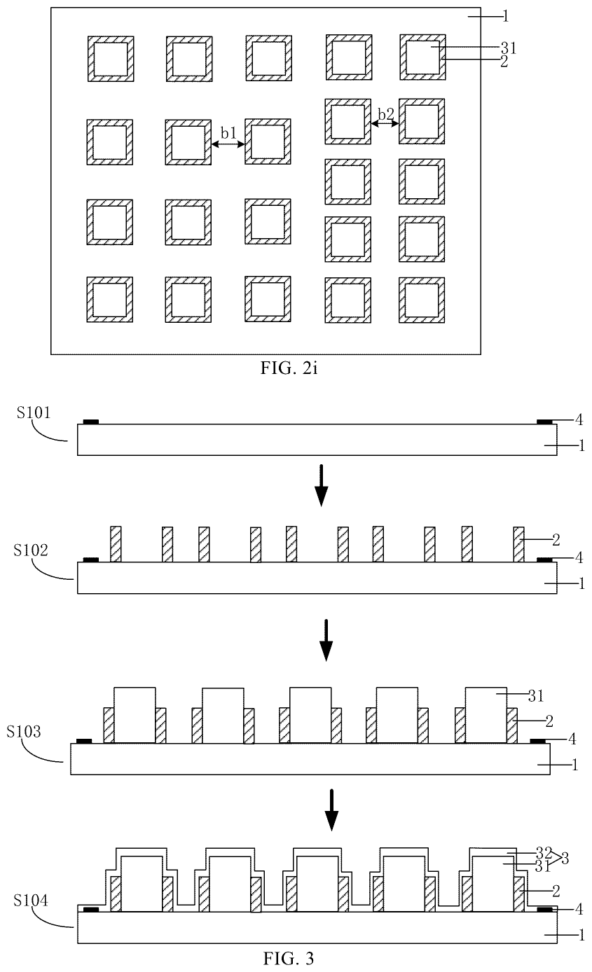

In order to solve the problems that the mass transfer technology by using the PDMS stamp is incompatible with the eutectic bonding technology and that the PDMS stamp cannot realize large-size transfer, in a first aspect, an embodiment of the present disclosure provides a stamp. Referring to FIG. 2a which is a schematic top view illustrating a structure of a stamp according to an embodiment of the present disclosure, and FIG. 2b which is a schematic cross-sectional view illustrating a structure of the stamp shown in FIG. 2a taken along a cutting line AA′, the stamp includes: a substrate 1; a plurality of position limiting structures 2, which are located on one side of the substrate 1 and spaced apart from each other; and a plurality of transfer structures 3, which are located on the one side of the substrate 1 where the position limiting structures 2 are located and are spaced apart from each other. The plurality of position limiting structures 2 are in one-to-one correspondence with the plurality of transfer structures 3. Each position limiting structure 2 surrounds a periphery of a corresponding transfer structure 3, and an orthogonal projection of each position limiting structure 2 on the substrate 1 does not overlap with an orthogonal projection of the corresponding transfer structure 3 on the substrate 1. A distance h1 between an end surface of an end, which is distal to the substrate 1, of each transfer structure 3 and the substrate 1 is greater than a distance h2 between an end surface of an end, which is distal to the substrate 1, of a corresponding position limiting structure 2 and the substrate 1.

The stamp can be used for transferring micro LED devices. The micro LED devices may be firstly fixed on a transfer substrate, and the plurality of transfer structures 3 are in one-to-one correspondence with and transfer the micro LED devices on the transfer substrate, so as to transfer the micro LED devices to a driving substrate. Since the distance h1 between the end surface of the end, which is distal to the substrate 1, of each transfer structure 3 and the substrate 1 is greater than the distance h2 between the end surface of the end, which is distal to the substrate 1, of the corresponding transfer structure 2 and the substrate 1, it can be mainly avoided that the corresponding position limiting structure 2 is in direct contact with the driving substrate during the process of transferring a micro LED device by each transfer structure 3, this is because each position limiting structure 2 mainly plays a position limiting role on the corresponding transfer structure 3, and the contact of the position limiting structure 2 with the driving substrate may have an influence on the alignment bonding of the micro LED device and the driving substrate.

Compared with a stamp structure formed by making a base substrate and protrusions have a one-piece structure in the related art, the plurality of transfer structures 3, which are formed by arranging the plurality of transfer structures 3 spaced apart from each other on the substrate 1, tend to have a same height, such that the heights of the plurality of transfer structures 3 are better in uniformity, which is beneficial to improving the yield of transfer and bonding of transferring the micro LED devices by adopting the stamp. Further, by arranging the position limiting structures 2, which can limit the positions and the transverse expansions (i.e., expansions in a direction parallel to a main surface of the substrate 1) of the respective transfer structures 3, the transfer structures 3 cannot have a transverse displacement relative to the substrate 1 due to thermal expansion during a eutectic bonding process for bonding a connecting terminal of a micro LED device and a connecting terminal of the driving substrate together under a high temperature and a high pressure, and thus the connecting terminal of the micro LED device and the connecting terminal of the driving substrate are prevented from having an alignment deviation in the eutectic bonding process under the high temperature and the high pressure, thereby improving the yield of transfer and bonding of transferring the micro LED device by adopting the stamp. In addition, based on the beneficial effects of the stamp in the above two aspects, the stamp according to an embodiment of the present disclosure can be manufactured to have a larger size, such that the transfer and bonding efficiency of transferring micro LED devices by using the stamp is improved.

In some embodiments, each transfer structure 3 includes a protrusion 31 and a viscosity adjustable layer 32 which are superposed together in sequence away from the substrate 1, and an orthogonal projection of the viscosity adjustable layer 32 on the substrate 1 coincides with an orthogonal projection of the protrusion 31 on the substrate 1. A surface of the viscosity adjustable layer 32 distal to the substrate 1 is configured to contact with and stick to a micro LED device, and during a transfer process of the micro LED device, the viscosity adjustable layer 32, on one hand, can be stuck to the micro LED device so as to pick up the micro LED device, and on the other hand, can be separated from the micro LED device so as to release the micro LED device, thereby transferring the micro LED device from the transfer substrate to the driving substrate.

An embodiment of the present disclosure further provides a stamp, as shown in FIG. 2c which is a schematic cross-sectional view illustrating another structure of the stamp shown in FIG. 2a taken along the cutting line AA′, where the stamp includes: a substrate 1; a plurality of position limiting structures 2 which are located on one side of the substrate 1 and spaced apart from each other; a plurality of protrusions 31 which are located on the one side of the substrate 1 where the position limiting structures 2 are located and are spaced apart from each other, the plurality of position limiting structures 2 are in one-to-one correspondence with the plurality of protrusions 31, each position limiting structure 2 surrounds a periphery of a corresponding protrusion 31, an orthogonal projection of each position limiting structure 2 on the substrate 1 does not overlap with an orthogonal projection of the corresponding protrusion 31 on the substrate 1, and a distance h3 between an end surface of an end, which is distal to the substrate 1, of each protrusion 31 and the substrate 1 is greater than the distance h2 between the end surface of the end, which is distal to the substrate 1, of a corresponding position limiting structure 2 and the substrate 1; and a viscosity adjustable layer 32 located on a side, which is distal to the substrate 1, of the position limiting structures 2 and the protrusions 31, and an orthogonal projection of the viscosity adjustable layer 32 on the substrate 1 covers at least the protrusions 31.

Portions of a surface, which is distal to the substrate 1, of the viscosity adjustable layer 32 whose orthogonal projections on the substrate 1 respectively coincide with orthogonal projections of the protrusions 31 on the substrate 1, are configured to contact with and stick to micro LED devices, and during a transfer process of the micro LED devices, the viscosity adjustable layer 32, on one hand, can be stuck with the micro LED devices so as to pick up the micro LED devices, and on the other hand, can be separated from the micro LED devices so as to release the micro LED devices, thereby transferring the micro LED devices from the transfer substrate to the driving substrate. Since the distance h3 between the end surface of the end, which is distal to the substrate 1, of each protrusion 31 and the substrate 1 is greater than the distance h2 between the end surface of the end, which is distal to the substrate 1, of the corresponding position limiting structure 2 and the substrate 1, it can be mainly avoided that the position limiting structures 2 are in direct contact with the driving substrate during the process of transferring micro LED devices by the protrusions 31 and the viscosity adjustable layer 32, this is because each position limiting structure 2 mainly plays a position limiting role on the corresponding protrusion 31, and the contact of the position limiting structures 2 with the driving substrate may have an influence on the alignment bonding of the micro LED devices and the driving substrate.

Compared with the stamp structure formed by making the base substrate and protrusions have a one-piece structure in the related art, the plurality of protrusions 31, which are formed by arranging the plurality of protrusions 31 spaced apart from each other on the substrate 1, tend to have a same height, such that the heights of the plurality of protrusions 31 are better in uniformity, which is beneficial to improving the yield of transfer and bonding of transferring the micro LED devices by adopting the stamp. Further, by arranging the position limiting structures 2, which can limit the positions and the transverse expansions (i.e., expansions in a direction parallel to a main surface of the substrate 1) of the respective protrusions 31, the protrusions 31 cannot have a transverse displacement relative to the substrate 1 due to thermal expansion during a eutectic bonding process for bonding a connecting terminal of a micro LED device and a connecting terminal of the driving substrate together under a high temperature and a high pressure, and thus the connecting terminal of the micro LED device and the connecting terminal of the driving substrate are prevented from having an alignment deviation in the eutectic bonding process under the high temperature and the high pressure, thereby improving the yield of transfer and bonding of transferring the micro LED device by adopting the stamp. In addition, based on the beneficial effects of the stamp in the above two aspects, the stamp according to an embodiment of the present disclosure can be manufactured to have a larger size, such that the transfer and bonding efficiency of transferring micro LED devices by using the stamp is improved. In addition, based on the beneficial effects of the stamp in the above two aspects, the stamp according to an embodiment of the present disclosure can be manufactured to have a larger size, such that the transfer and bonding efficiency of transferring micro LED devices by using the stamp is improved.

In some embodiments, referring to FIG. 2a, a shape of the orthogonal projection of each position limiting structure 2 on the substrate 1 is a ring, and the orthogonal projection of a protrusion 31 on the substrate 1 and the orthogonal projection of the position limiting structure 2 corresponding to the protrusion 31 on the substrate 1 abut on each other. With such an arrangement, the position limiting structures 2 can effectively limit the positions and the transverse expansions (i.e., expansions in a direction parallel to a main surface of the substrate 1) of the respective protrusions 31, such that the protrusions 31 cannot have a transverse displacement relative to the substrate 1 due to thermal expansion during a eutectic bonding process for bonding a connecting terminal of a micro LED device and a connecting terminal of the driving substrate together under a high temperature and a high pressure, and thus the connecting terminal of the micro LED device and the connecting terminal of the driving substrate are prevented from having an alignment deviation in the eutectic bonding process under the high temperature and the high pressure, thereby improving the yield of transfer and bonding of transferring the micro LED device by adopting the stamp.

In some embodiments, referring to FIG. 2c, ⅓ of a height of a protrusion 31≤a height of a corresponding position limiting structure 2 ≤¾ of the height of the protrusion 31. With such a configuration, the position limiting structures 2 can limit the positions and the transverse expansions (i.e., expansions in a direction parallel to a main surface of the substrate 1) of the respective protrusions 31, and it can be avoided that the position limiting structures 2 are in direct contact with the driving substrate, this is because each position limiting structure 2 mainly plays a position limiting role on the corresponding protrusion 31, and the contact of the position limiting structures 2 with the driving substrate may have an influence on the alignment bonding of the micro LED devices and the driving substrate. Here, the height of the protrusion 31 is the distance h3 between the end surface of the end, which is distal to the substrate 1, of the protrusion 31 and the substrate 1, and the height of the position limiting structure 2 is the distance h2 between the end surface of the end, which is distal to the substrate 1, of the position limiting structure 2 and the substrate 1.

In some embodiments, the height of each protrusion 31 ranges from 5 μm to 20 μm. Here, the height of a protrusion 31 is a thickness of the protrusion 31 in a direction away from the substrate 1. The set height range can, on one hand, achieve good uniformity in heights of the plurality of protrusions 31 on the substrate 1, and on the other hand, enable the combination of the protrusions 31 with the viscosity adjustable layer 32 to achieve effective transfer of micro LED devices, thereby improving a transfer yield.

In some embodiments, a linewidth a of the ring of each position limiting structure 2 ranges from 2 μm to 30 μm. The range of the linewidth a of the ring can ensure that the positions and the transverse expansions (i.e., expansions in the direction parallel to a main surface of the substrate 1) of the protrusions 31 can be stably limited by the respective position limiting structures 2.

In some embodiments, a thickness of the viscosity adjustable layer 32 is in a range of 1 μm to 5 μm. The viscosity adjustable layer 32 having a thickness in this range can effectively pick up and release the micro LED devices, thereby effectively transferring the micro LED devices from the transfer substrate to the driving substrate.

In some embodiments, referring to FIG. 2d which is a schematic cross-sectional view illustrating another structure of the stamp shown in FIG. 2a taken along the cutting line AA′, the viscosity adjustable layer 32 includes an adhesive sub-layer 322 and a dissociating sub-layer 321, and the dissociating sub-layer 321 and the adhesive sub-layer 322 are superposed together in sequence away from the substrate 1. A thickness of the adhesive sub-layer 322 is in a range of 1 μm to 5 μm, and a thickness of the dissociating sub-layer 321 is in a range of 0.1 μm to 2 μm. The adhesive sub-layer 322 can stick to and pick up the micro LED devices by being made of a material of adhesive, and the dissociating sub-layer 321 can be disconnected to and release the micro LED devices by debonding through a material, such that the micro LED devices can be picked up and released, and are transferred from the transfer substrate to the driving substrate effectively.

In some embodiments, referring to FIGS. 2a, 2e and 2f, among which FIG. 2e is a schematic top view illustrating a structure of another stamp according to an embodiment of the present disclosure, and FIG. 2f is a schematic top view illustrating a structure of another stamp according to an embodiment of the present disclosure, a shape of the orthogonal projection of each protrusion 31 on the substrate 1 includes a circle, a rectangle, a triangle, or a polygon.

In some embodiments, referring to FIGS. 2a, 2e and 2f, the plurality of protrusions 31 are arranged to be equally spaced apart from each other in an array. Referring to FIG. 2g which is a schematic top view illustrating a structure of another stamp according to an embodiment of the present disclosure, the orthogonal projections of the plurality of protrusions 31 on the substrate 1 have a same (i.e., identical) shape, and the orthogonal projections of any two adjacent columns of the protrusions 31 on the substrate 1 have different orientations (or are orientated in different directions), respectively. As shown in FIG. 2g, the orthogonal projections of the plurality of protrusions 31 on the substrate 1 are all triangles, and the triangles of the orthogonal projections of any two adjacent columns of protrusions 31 on the substrate 1 have different orientations (or are orientated in different directions), respectively. Referring to FIG. 2h which is a schematic top view illustrating a structure of another stamp according to an embodiment of the present disclosure, the orthogonal projections of one part of the plurality of protrusions 31 on the substrate 1 have a shape different from a shape of the orthogonal projections of the other part of the plurality of protrusions 31 on the substrate 1. As shown in FIG. 2h, the orthogonal projections of the one part of the plurality of protrusions 31 on the substrate 1 have a shape of rectangle, whereas the orthogonal projections of the other part of the plurality of protrusions 31 on the substrate 1 have a shape of circle.

In some embodiments, referring to FIG. 2i which is a schematic top view illustrating a structure of another stamp according to an embodiment of the present disclosure, some of the plurality of protrusions 31 are arranged in an array to be spaced apart from each other by a first distance b1, and others of the plurality of protrusions 31 are arranged in an array to be spaced apart from each other by a second distance b2, where the first distance b1 is greater than the second distance b2.

In some embodiments, a material of each protrusion 31 includes any one of polymethyl methacrylate (PMMA), propylene glycol methyl ether acetate, silicone resin, or acrylic resin.

In some embodiments, a material of each position limiting structure 2 includes any one of silicon oxide, silicon nitride, silicon oxynitride, copper, aluminum, molybdenum, or silver.

In some embodiments, a material of the viscosity adjustable layer 32 includes any one of UV viscosity-reducing glue, thermal foaming viscosity-reducing glue, or laser dissociating glue. The main material of the UV viscosity-reducing glue includes any one of epoxy acrylate, polyurethane acrylate, polyether acrylate, polyester acrylate, or acrylic resin. The main material of the thermal foaming viscosity-reducing glue includes one or more of styrene butadiene rubber, polyisoprene rubber, polyisobutylene rubber, butyl rubber (which may also be referred to as “isobutylene isoprene rubber”), chloroprene rubber (which may also be referred to as “neoprene”), nitrile rubber (which may also be referred to as “nitrile butadiene rubber”), and another synthetic rubber, foaming particles are mixed in the main material of the thermal foaming viscosity-reducing glue, a size of each of the foaming particles is in a range of 0.5 μm to 5 μm, and a filling rate of the foaming particles in the main material ranges from 2% to 10%. The main material of the laser dissociating glue includes one or more of acrylic resin, epoxy resin, and polymethyl methacrylate (PMMA). The UV viscosity-reducing glue has a certain adhesion ability (e.g., a certain viscosity) and can be debonding (i.e., can lose the adhesion ability) under irradiation by UV light. The thermal foaming viscosity-reducing glue has a certain adhesion ability and can be debonding under a heating action. The laser dissociating glue has a certain adhesion ability and can be debonding under laser irradiation.

In some embodiments, the main material of the adhesive sub-layer 322 includes one or more of polyether resin, epoxy resin, acrylic resin, polyisoprene resin, and polyisobutylene resin. The main material of the dissociating sub-layer 321 includes one or more of polyimide resin, acrylic resin, epoxy resin, and the like. The main material adopted for the dissociating sub-layer 321 is a laser dissociating glue which has no viscosity and only has a property of being dissociated by laser, and molecular chains of the main material of the dissociating sub-layer 321 are broken under irradiation by laser with a wavelength of 255 nm, 266 nm, 308 nm or 355 nm to generate gas, such that layers on both sides of the dissociating sub-layer 321 are dissociated. The adhesive sub-layer 322 has a certain adhesion ability, and can realize adhesive bonding between the protrusions 31 and respective micro LED devices.

In some embodiments, referring to FIGS. 2b, 2c and 2d, the stamp further includes a plurality of alignment marks 4, which are located on the side of the substrate 1 where the position limiting structures 2 are located, and are located in a peripheral region or a central region of the substrate 1. An orthogonal projection of each alignment mark 4 on the substrate 1 does not overlap with the orthogonal projection of any one of the position limiting structures 2 on the substrate 1 or the orthogonal projection of any one of the protrusions 31 on the substrate 1, and the alignment marks 4 are located on a side of the viscosity adjustable layer 32 proximal to the substrate 1.

The alignment marks 4 are used for aligning the protrusions 31 and the micro LED devices when the stamp picks up the micro LED devices from the transfer substrate, and are also used for aligning the connecting terminals of the micro LED devices and the connecting terminals on the driving substrate when the stamp transfers the micro LED devices to the driving substrate.

In some embodiments, each of the alignment marks 4 is made of a metal material, such as molybdenum, titanium, aluminum, silver, or the like. In some embodiments, a shape of an orthogonal projection of each alignment mark 4 on the substrate 1 includes a rectangle, a circle, a cross, or the like. A size of each alignment mark 4 may be determined according to a recognition accuracy of an alignment device, and is not particularly limited herein.

In a second aspect, based on the above structures of any one of the above stamps, an embodiment of the present disclosure further provides a method for manufacturing any one of the above stamps. Referring to FIG. 3 which is a flowchart of a method for manufacturing a stamp according to an embodiment of the present disclosure, the method includes the following steps S102 to S104. Step S102 includes forming a plurality of position limiting structures 2 on a side of the substrate 1 by adopting a patterning process.

Step S103 includes forming a plurality of protrusions 31 on the side of the substrate 1 where the above step has been completed by using a patterning process. The plurality of protrusions 31 and the plurality of position limiting structures 2 are located on a same side of the substrate 1.

Step S104 includes forming a viscosity adjustable layer 32 on the side of the substrate 1 where the above steps have been completed by using a patterning process. The viscosity adjustable layer 32 is located on a side of the position limiting structures 2 and the protrusions 31 distal to the substrate 1, and the orthogonal projection of the viscosity adjustable layer 32 on the substrate 1 covers at least the protrusions 31.

In the present embodiment, the method may further include step S101 prior to step S102, and step S101 includes forming a plurality of alignment marks 4 on the side of the substrate 1 by using a patterning process. The patterning process for forming the alignment marks 4 includes steps of depositing to form a film, photoresist coating, exposure, development, etching, and the like, which will not be repeated hereinafter.

The method for manufacturing the stamp according to the embodiments of the present disclosure is realized through a traditional patterning process, and thus the manufacturing process thereof is simple, the manufacturing precision thereof is high, the manufacturing cost thereof is low, and the stamp can be manufactured to have a large size. The manufactured stamp can not only improve the yield of transfer and bonding of the micro LED devices, but also improve the efficiency of transfer and bonding of the micro LED devices.

In some embodiments, step S102 of forming a plurality of position limiting structures 2 on a side of the substrate 1 by adopting a patterning process includes the following steps S1021 to S1026. Step S1021 includes depositing a position limiting structure film on the side of the substrate.

In the present step, the position limiting structure film may be made of an inorganic insulating material such as silicon nitride, silicon oxide, or silicon oxynitride, and in this case the position limiting structure film is formed by chemical vapor deposition; alternatively, the position limiting structure film may be made of a metal material such as copper, aluminum, molybdenum, or silver, and in this case the position limiting structure film is formed by sputtering deposition.

Step S1022 includes coating a photoresist layer on a side of the position limiting structure film distal to the substrate.

Step S1023 includes exposing the photoresist layer by using a mask including patterns of the position limiting structures.

Step S1024 includes developing to remove the photoresist in exposed regions of the photoresist layer.

In the present step, portions of the photoresist layer which are in regions outside the patterns of the position limiting structures are developed and removed.

Step S1025 includes etching and removing portions of the position limiting structure film which are not covered by the photoresist by a dry etching process or a wet etching process to form the patterns of the plurality of position limiting structures.

In the present step, the position limiting structure film made of the inorganic insulating material is removed by the dry etching process, and the position limiting structure film made of the metal material is removed by the wet etching process.

Step S1026 includes stripping off the residual photoresist.

In some embodiments, step S103 of forming a plurality of protrusions 31 on the side of the substrate 1 where the above step has been completed using a patterning process includes coating an organic resin material layer on the side of the substrate.

Step S103 further includes exposing the organic resin material layer by using a mask including patterns of the protrusions.

Step S103 further includes developing to remove portions of the organic resin material layer which are in exposed regions to form the patterns of the plurality of protrusions.

In some embodiments, step S104 of forming a viscosity adjustable layer 32 on the side of the substrate 1 where the above steps have been completed by using a patterning process includes coating the viscosity adjustable layer on the side of the substrate by a spin coating process, a scrape coating process, or a slit coating process.

The viscosity adjustable layer is a continuous layer covering the substrate.

In some embodiments, step S104 of forming a viscosity adjustable layer 32 on the side of the substrate 1 where the above steps have been completed by using a patterning process includes coating a viscosity adjustable film on the side of the substrate.

Step S104 further includes exposing the viscosity adjustable film by using a mask including a pattern of the viscosity adjustable layer.

Step S104 further includes developing to remove portions of the viscosity adjustable film which are in exposed regions, thereby forming the pattern of the viscosity adjustable layer. Here, the orthogonal projection of the viscosity adjustable layer on the substrate does not coincide with the substrate but partially overlaps with the substrate, and the orthogonal projection of the viscosity adjustable layer on the substrate covers at least the orthogonal projections of the protrusions on the substrate.

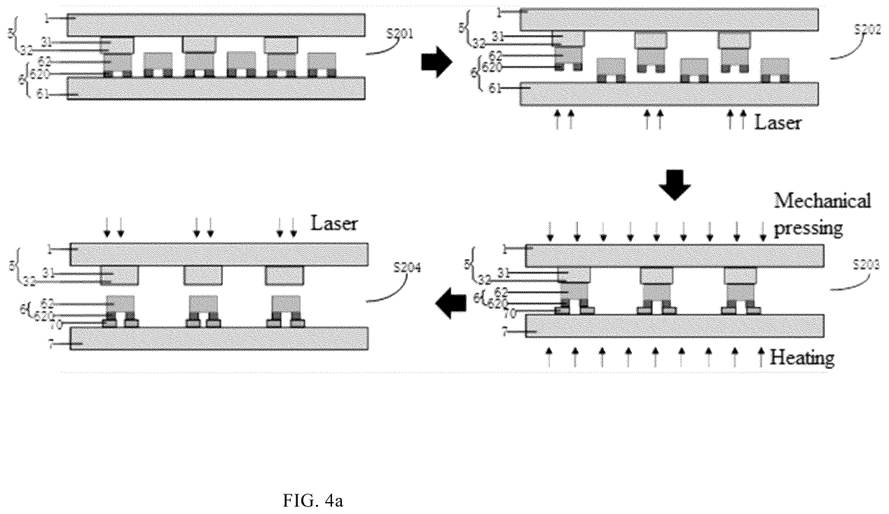

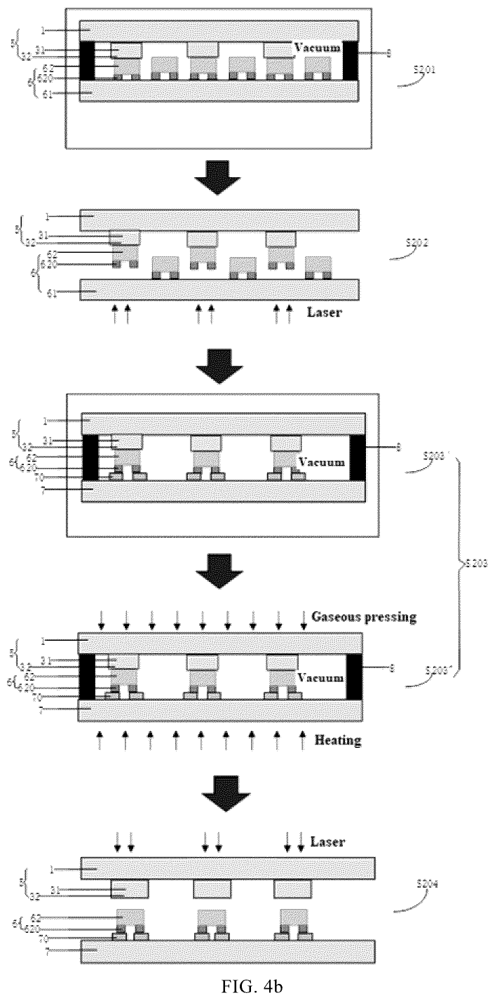

In a third aspect, an embodiment of the present disclosure further provides a mass transfer method, and referring to FIG. 4a which is a process flow diagram of a mass transfer method according to an embodiment of the present disclosure, and FIG. 4b which is a process flow diagram of another mass transfer method according to an embodiment of the present disclosure, each mass transfer method includes the following steps S201 to S204. Step S201 includes pressing a stamp 5 and a transfer substrate 6 together.

Here, the stamp 5 is the stamp according to any one of the foregoing embodiments, and the transfer substrate 6 includes a base plate 61 and a plurality of light emitting diodes 62 arranged on a side of the base plate 61. The plurality of protrusions 31 of the stamp 5 are in one-to-one correspondence with at least some of the light emitting diodes 62, the viscosity adjustable layer 3, of which the orthogonal projection on the base plate 61 overlaps with the orthogonal projections of the protrusions 31 on the base plate 61, contacts with and stick to the light emitting diodes 62, and the orthogonal projections of the protrusions 31 on the base plate 61 covers the light emitting diodes 62, respectively.

In some embodiments, the light emitting diodes 62 may be normal-size light emitting diodes (i.e., LEDs), micro light emitting diodes (i.e., micro LEDs), or mini light emitting diodes (i.e., mini LEDs).

In some embodiments, the pressing the stamp 5 and the transfer substrate 6 together includes mechanically pressing (see FIG. 4a) or gaseously pressing (see FIG. 4b).

In some embodiments, referring to FIG. 4b, in the case of gaseously pressing, the stamp 5 and the transfer substrate 6 are attached together in a vacuum attaching device and sealed by a frame sealant 8, and the viscosity adjustable layer 32 is in contact with and bonded to the light emitting diodes 62 under the action of the external atmospheric pressure.

Step S202 includes pulling the stamp 5 away from the transfer substrate 6 to pick up at least some of the light emitting diodes 62 on the transfer substrate 6.

In the present step, the stamp 5 is attached to the light emitting diodes 62 through the viscosity adjustable layer 32 or the adhesive sub-layer 322 of the viscosity adjustable layer 32, and when the stamp 5 is pulled away from the transfer substrate 6, an attaching force between the viscosity adjustable layer 32 or the adhesive sub-layer 322 and the light emitting diodes 62 is greater than a bonding force between the light emitting diodes 62 and the substrate 61, such that the light emitting diodes 62 are separated from the substrate 61, and are picked up.

In some embodiments, the stamp 5 is pulled away from the transfer substrate 6, and at the same time, laser irradiation is performed on portions of the transfer substrate 6 corresponding to the positions of the light emitting diodes 62 to be picked up, such that the light emitting diodes 62 to be picked up are separated from the base plate 61. That is, the light emitting diodes 62 and the base plate 61 may be fixedly connected together by a laser separable material (e.g., a laser peelable adhesive), and when the stamp 5 picks up the light emitting diodes 62 from the transfer substrate 6, laser irradiation is performed on a side of the transfer substrate 6, such that the light emitting diodes 62 are separated from the base plate 61.

Step S203 includes transferring the picked up light emitting diodes 62 to the driving substrate 7 by the stamp 5, making first connecting terminals 620 of the light emitting diodes 62 correspondingly attached to second connecting terminals 70 on the driving substrate 7, applying pressure to the stamp 5 and at the same time heating the driving substrate 7, thereby bonding the first connecting terminals 620 to the second connecting terminals 70, respectively.

In some embodiments, referring to FIG. 4b, S203 includes the following steps S203′ and S203″. Step S203′ includes transferring the light emitting diodes 62 to the driving substrate 7 by the stamp 5, attaching the stamp 5 and the driving substrate 7 in the vacuum attaching device and sealing them by the frame sealant 8, and making the first connecting terminals 620 of the light emitting diodes 62 be in contact with and attached to the second connecting terminals 70 on the driving substrate 7 under the action of the external atmospheric pressure. Step S203″ includes gaseously pressing the stamp 5 and at the same time heating the driving substrate 7, thereby bonding the first connecting terminals 620 to the second connecting terminals 70, respectively.

In some embodiments, a pressure applied to the stamp 5 is any one of the pressure values shown in Table 1, and a heating temperature for the driving substrate 7 is any one of the temperature values shown in Table 1. The first connecting terminals 620 and the second connecting terminals 70 are subjected to eutectic bonding together under the pressure and heating process conditions shown in Table 1.

In some embodiments, there are two first connecting terminals 620 and two second connecting terminals 70, and the two first connecting terminals 620 and the two second connecting terminals 70 are connected to each other in one-to-one correspondence.

Step S204 includes separating the stamp 5 from the picked up light emitting diodes 62.

In the present step, in the case where the viscosity adjustable layer 32 or the dissociating sub-layer is the UV viscosity-reducing glue, UV light irradiation is performed on the stamp 5 to separate the stamp 5 from the light emitting diodes 62.

In some embodiments, in the case where the viscosity adjustable layer 32 or the dissociating sub-layer is the thermal foaming viscosity-reducing glue, the stamp 5 is heated, and when the temperature of the stamp 5 is heated up to 90° C. to 150° C., the stamp 5 is separated from the light emitting diodes 62.

In some embodiments, in the case where the viscosity adjustable layer 32 or the dissociating sub-layer is the laser dissociating glue, the stamp 5 is irradiated with laser light to separate the stamp 5 from the light emitting diodes 62. A wavelength of the laser light includes 255 nm, 266 nm, 308 nm, or 355 nm.

In the mass transfer method according to any one of the foregoing embodiments of the present disclosure, by adopting the stamp according to any one of the foregoing embodiments, not only multiple transfers of the light emitting diodes of the transfer substrate can be realized in batches, but also the plurality of light emitting diodes of the transfer substrate can be transferred once, such that the yield of transfer and bonding of the light emitting diodes is improved, and the efficiency of transfer and bonding of the light emitting diodes is improved.

In a fourth aspect, an embodiment of the present disclosure further provides a transfer device, which includes the stamp according to any one of the foregoing embodiments.

The transfer device can transfer a huge amount of light emitting diodes (i.e., LEDs), micro light emitting diodes (i.e., micro LEDs), and mini light emitting diodes (i.e., mini LEDs).

By including the stamp according to any one of the foregoing embodiments, the transfer device can transfer the plurality of light emitting diodes of the transfer substrate once, such that the transfer device has an improved yield of transfer and bonding of the light emitting diodes and an improved efficiency of transfer and bonding of the light emitting diodes.

It will be understood that the foregoing embodiments are merely exemplary embodiments employed to illustrate the principles of the present disclosure, and the present disclosure is not limited thereto. It will be apparent to one of ordinary skill in the art that various changes and modifications may be made therein without departing from the spirit and scope of the present disclosure, and such changes and modifications are to be considered to fall within the scope of the present disclosure.

1. A stamp, comprising:
a substrate;
a plurality of position limiting structures located on a side of the substrate and spaced apart from each other; and
a plurality of transfer structures, which are located on the side of the substrate where the position limiting structures are located, and are spaced apart from each other, wherein
the plurality of position limiting structures are in one-to-one correspondence with the plurality of transfer structures;
each position limiting structure surrounds a periphery of a corresponding transfer structure, and an orthogonal projection of the position limiting structure on the substrate does not overlap with an orthogonal projection of the corresponding transfer structure on the substrate; and
a distance between an end surface of an end, which is distal to the substrate, of each transfer structure and the substrate is greater than a distance between an end surface of an end, which is distal to the substrate, of a corresponding position limiting structure and the substrate.

2. The stamp according to claim 1, wherein each transfer structure comprises a protrusion and a viscosity adjustable layer which are superposed together in sequence away from the substrate, and
an orthogonal projection of the viscosity adjustable layer on the substrate coincides with an orthogonal projection of the protrusion on the substrate.

3. A stamp, comprising:
a substrate;
a plurality of position limiting structures located on a side of the substrate and spaced apart from each other; and
a plurality of protrusions, which are located on the side of the substrate where the position limiting structures are located, and are spaced apart from each other, wherein
the plurality of position limiting structures are in one-to-one correspondence with the plurality of protrusions;
each position limiting structure surrounds a periphery of a corresponding protrusion, and an orthogonal projection of the position limiting structure on the substrate does not overlap with an orthogonal projection of the corresponding protrusion on the substrate;
a distance between an end surface of an end, which is distal to the substrate, of each protrusion and the substrate is greater than a distance between an end surface of an end, which is distal to the substrate, of a corresponding position limiting structure and the substrate; and
the stamp further comprises a viscosity adjustable layer located on a side, which is distal to the substrate, of the position limiting structures and the protrusions, and an orthogonal projection of the viscosity adjustable layer on the substrate covers at least the protrusions.

4. The stamp according to claim 2, wherein a shape of the orthogonal projection of each position limiting structure on the substrate is a ring, and
the orthogonal projection of each protrusion on the substrate and the orthogonal projection of a corresponding position limiting structure on the substrate 1 abut on each other.

5. The stamp according to claim 2, wherein ⅓ of a height of each protrusion≤a height of a corresponding position limiting structure ≤¾ of the height of the protrusion.

6. The stamp according to claim 5, wherein the height of each protrusion is in a range of 5 μm to 20 μm.

7. The stamp according to claim 4, wherein a linewidth of the ring of each position limiting structure is in a range of 2 μm to 30 μm.

8. The stamp according to claim 2, wherein a thickness of the viscosity adjustable layer is in a range of 1 μm to 5 μm.

9. The stamp according to claim 2, wherein the viscosity adjustable layer comprises an adhesive sub-layer and a dissociating sub-layer, and the dissociating sub-layer and the adhesive sub-layer are superposed together in sequence away from the substrate 1;
a thickness of the adhesive sub-layer is in a range of 1 μm to 5 μm; and
a thickness of the dissociating sub-layer is in a range of 0.1 μm to 2 μm.

10. The stamp according to claim 2, wherein a shape of the orthogonal projection of each protrusion on the substrate comprises a circle, a rectangle, a triangle, or a polygon.

11. The stamp according to claim 10, wherein the plurality of protrusions are arranged in an array to be equally spaced apart from each other; and
orthogonal projections of the plurality of protrusions on the substrate have a same shape, and orthogonal projections of any two adjacent columns of the protrusions on the substrate have different orientations;
or
orthogonal projections of some of the plurality of protrusions on the substrate have a shape different from a shape of orthogonal projections of others of the plurality of protrusions on the substrate.

12. The stamp according to claim 10, wherein some of the plurality of protrusions are arranged in an array to be spaced apart from each other by a first distance, and others of the plurality of protrusions are arranged in an array to be spaced apart from each other by a second distance, where the first distance is greater than the second distance.

13. The stamp according to claim 2, wherein a material of each protrusion comprises any one of polymethyl methacrylate, propylene glycol methyl ether acetate, silicone resin, or acrylic resin.

14. The stamp according to claim 1, wherein a material of each position limiting structure comprises any one of silicon oxide, silicon nitride, silicon oxynitride, copper, aluminum, molybdenum, or silver.

15. The stamp according to claim 2, wherein a material of the viscosity adjustable layer comprises any one of UV viscosity-reducing glue, thermal foaming viscosity-reducing glue, or laser dissociating glue;
a main material of the UV viscosity-reducing glue comprises any one of epoxy acrylate, polyurethane acrylate, polyether acrylate, polyester acrylate, or acrylic resin;
a main material of the thermal foaming viscosity-reducing glue comprises one or more of styrene butadiene rubber, polyisoprene rubber, polyisobutylene rubber, butyl rubber, chloroprene rubber, and nitrile rubber, foaming particles are mixed in the main material of the thermal foaming viscosity-reducing glue, a size of each of the foaming particles is in a range of 0.5 μm to 5 μm, and a filling rate of the foaming particles in the main material ranges from 2% to 10%; and
a main material of the laser dissociating glue comprises one or more of acrylic resin, epoxy resin, and polymethyl methacrylate.

16. The stamp according to claim 9, wherein a main material of the adhesive sub-layer comprises one or more of polyether resin, epoxy resin, acrylic resin, polyisoprene resin, and polyisobutylene resin; and
a main material of the dissociating sub-layer comprises one or more of polyimide resin, acrylic resin, and epoxy resin.

17. The stamp according to claim 2, further comprising a plurality of alignment marks, which are located on the side of the substrate where the position limiting structures are located, and are located in a peripheral region or a central region of the substrate;
an orthogonal projection of each alignment mark on the substrate does not overlap with the orthogonal projection of any one of the position limiting structures on the substrate or the orthogonal projection of any one of the protrusions on the substrate, and
the alignment marks are located on a side of the viscosity adjustable layer proximal to the substrate.

18. A transfer device, comprising the stamp according to claim 1.

19. A method for manufacturing a stamp, the method comprising:
forming a plurality of position limiting structures on a side of a substrate by a patterning process;
forming a plurality of protrusions on the side of the substrate where the above step has been completed by a patterning process, wherein the plurality of protrusions and the plurality of position limiting structures are located on a same side of the substrate; and
forming a viscosity adjustable layer on the side of the substrate where the above steps have been completed by a patterning process, wherein the viscosity adjustable layer is located on a side of the position limiting structures and the protrusions distal to the substrate, and an orthogonal projection of the viscosity adjustable layer on the substrate covers at least the protrusions:
wherein the forming a plurality of position limiting structures on a side of a substrate by a patterning process comprises: depositing a position limiting structure film on the side of the substrate; coating a photoresist layer on a side of the position limiting structure film distal to the substrate; exposing the photoresist layer by using a mask comprising patterns of the position limiting structures; developing to remove photoresist in exposed regions of the photoresist layer, etching and removing portions of the position limiting structure film which are not covered by the photoresist by a dry etching process or a wet etching process to form the patterns of the plurality of position limiting structures; and stripping off the residual photoresist;
or
wherein the forming a plurality of protrusions on the side of the substrate where the above step has been completed by a patterning process comprises: coating an organic resin material layer on the side of the substrate, exposing the organic resin material layer by using a mask comprising patterns of the protrusions; and developing to remove portions of the organic resin material layer which are in exposed regions to form the patterns of the plurality of protrusion;
or
wherein the forming a viscosity adjustable layer on the side of the substrate where the above steps have been completed by a patterning process comprises: coating the viscosity adjustable layer on the side of the substrate by a spin coating process, a scrape coating process, or a slit coating process; or coating a viscosity adjustable film on the side of the substrate, exposing the viscosity adjustable film by using a mask comprising a pattern of the viscosity adjustable layer, and developing to remove portions of the viscosity adjustable film which are in exposed regions, thereby forming the pattern of the viscosity adjustable layer.

20-22. (canceled)

23. A mass transfer method, comprising:
pressing a stamp and a transfer substrate together, wherein the stamp is the stamp according to claim 3, the transfer substrate comprises a base plate and a plurality of light emitting diodes arranged on a side of the base plate, the plurality of protrusions of the stamp are in one-to-one correspondence with at least some of the light emitting diodes, the viscosity adjustable layer, of which an orthogonal projection on the base plate overlaps with orthogonal projections of the protrusions on the base plate, contacts with and stick to the light emitting diodes, and the orthogonal projections of the protrusions on the base plate covers the light emitting diodes, respectively;
pulling the stamp away from the transfer substrate to pick up at least some of the light emitting diodes on the transfer substrate;
transferring the picked up light emitting diodes to a driving substrate by the stamp, making first connecting terminals of each of the light emitting diodes correspondingly attached to second connecting terminals on the driving substrate, applying pressure to the stamp and at the same time heating the driving substrate, thereby bonding the first connecting terminals to the second connecting terminals, respectively; and
separating the stamp from the picked up light emitting diodes;
wherein each of the pressing a stamp and a transfer substrate together and the applying pressure to the stamp comprises mechanically pressing or gaseously pressing; and wherein in a case of gaseously pressing, the stamp and the transfer substrate are attached together in a vacuum attaching device and sealed by a frame sealant, and the viscosity adjustable layer is in contact with and bonded to the light emitting diodes under an action of an external atmospheric pressure; the light emitting diodes are transferred to the driving substrate by the stamp, the stamp and the driving substrate are attached together in the vacuum attaching device and sealed by the frame sealant, and the first connecting terminals of each of the light emitting diodes are in contact with and attached to the second connecting terminals on the driving substrate under the action of the external atmospheric pressure; and the stamp is gaseously pressed and at the same time the driving substrate is heated, thereby bonding the first connecting terminals to the second connecting terminals, respectively;
or
wherein the separating the stamp from the picked up light emitting diodes comprises: performing UV light irradiation on the stamp to separate the stamp from the light emitting diodes; or heating the stamp up to 90° C. to 150° C., to separate the stamp from the light emitting diodes; or irradiating the stamp with laser light to separate the stamp from the light emitting diodes, wherein a wavelength of the laser light includes 255 nm, 266 nm, 308 nm, or 355 nm;
or
the mass transfer method further comprises performing laser irradiation on portions of the transfer substrate corresponding to positions of the light emitting diodes to be picked up while the pulling the stamp away from the transfer substrate is performed, to separate the light emitting diodes to be picked up from the base plate.

24-27. (canceled)
